(19) United States
(12) Patent Application Publication
(10) Pub. No.: US 2007/0164367 A1
(43) Pub. Date: Jul. 19, 2007

(54) CMOS gates with solid-solution alloy tunable work functions

(75) Inventors: Leonard Forbes, Corvallis, OR (US); Paul A. Farrar, Bluffton, SC (US); Kie Y. Ahn, Chappaqua, NY (US)

Correspondence Address: SCHWEGMAN, LUNDBERG, WOESSNER & KLUTH, P.A., P.O. BOX 2938, MINNEAPOLIS, MN, 55402, US

(73) Assignee: Micron Technology, Inc.

(21) Appl. No.: 11/333,885

(22) Filed: Jan. 18, 2006

(51) Int. Cl. H01L 21/8238; H01L 29/94; H01L 29/76

(52) U.S. Cl. 257/369; 438/199

(57) ABSTRACT

Gates of at least one of NMOS transistors and PMOS transistors of a CMOS integrated circuit are formed with a solid-solution alloy of at least two metals. The work function of the gate electrode is tunable by controlling the selection of the metals or the relative proportion of the metals that form a layer of the solid-solution alloy. In one embodiment, a layer of each metal is deposited onto the gate area of a MOS transistor. At least one metal is deposited using atomic layer deposition. The solid-solution alloy is formed by annealing subsequent to the deposition of the metals.

### CROSS-REFERENCE TO RELATED APPLICATIONS

This application is related to co-pending, commonly assigned U.S. patent application Ser. No. ______, entitled “CMOS GATES WITH INTERMETALLIC COMPOUND TUNABLE WORK FUNCTIONS,” filed on ______ (Attorney Docket No. 1303.160US1); U.S. patent application Ser. No. 11/038,730, entitled “ATOMIC LAYER DEPOSITION OF CMOS GATES WITH VARIABLE WORK FUNCTIONS,” filed on Jan. 20, 2005; U.S. patent application Ser. No. 10,929,822, entitled “ATOMIC LAYER DEPOSITION OF CMOS GATES WITH VARIABLE WORK FUNCTIONS,” filed on Aug. 30, 2004; U.S. patent application Ser. No. 10/754,842, entitled “ATOMIC LAYER DEPOSITION OF CMOS GATES WITH VARIABLE WORK FUNCTIONS,” filed on Jan. 9, 2004; and U.S. patent application Ser. No. 10/225,605, entitled “ATOMIC LAYER DEPOSITION OF CMOS GATES WITH VARIABLE WORK FUNCTIONS,” filed on Aug. 22, 2002, which are hereby incorporated by reference in their entirety.

### TECHNICAL FIELD

This document relates generally to semiconductor integrated circuit technology and particularly, but not by way of limitation, to complementary metal-oxide semiconductor (CMOS) transistors having gates with work functions tunable using solid-solution alloys.

### BACKGROUND

Conventional n-type doped polysilicon gate electrodes in CMOS technology have two problems. One problem is that the polysilicon is conductive but there can still be a surface region which can be depleted of carriers under bias conditions. Commonly referred to as gate depletion, this appears as an extra gate insulator thickness and contributes to the equivalent oxide thickness. While this region is thin, on the order of a few angstroms (Å), it becomes appreciable as gate oxide thicknesses are below 2 nm or 20 Å. Another problem is that the work function is not optimum for both NMOS and PMOS transistors. Historically, this was compensated for by threshold voltage adjustment implantations. However, as the devices become smaller, with channel lengths of less than 1000 Å and consequently surface space charge regions of less than 100 Å, it becomes more and more difficult to perform such implantations. Threshold voltage control becomes an important consideration as power supply voltage is reduced to about one volt. Optimum threshold voltages of both NMOS and PMOS transistors need to have a magnitude of around 0.3 volts.

The work function of the gate electrode, which is the energy needed to extract an electron, must be compatible with the barrier height of the semiconductor material. For PMOS transistors, the required work function is about 5.0 eV. Achieving the lower work function needed by NMOS transistors, which is about 4.1 eV, has been more difficult. FIGS. 1A-1C illustrate the desired energy band diagrams and work functions for NMOS and PMOS transistors. As illustrated in FIG. 1A, metals with work functions of around 4.1 eV will result in NMOS threshold voltages around zero volts on bulk CMOS devices. As illustrated in FIG. 1B, about 0.6 eV band bending will occur in the p-type silicon substrate and 0.3 eV potential drop will occur across the gate oxide. If a positive NMOS threshold voltage of larger magnitude is required, the work function of the metal gate should be larger, such as 4.3 eV, which will give a threshold around 0.2 volts. Metals with work functions of around 5.0 eV will result in PMOS threshold voltages around zero volts on bulk CMOS devices. As illustrated in FIG. 1C, about 0.6 eV band bending will occur in the p-type silicon substrate and 0.3 eV potential drop will occur across the gate oxide. If a negative PMOS threshold voltage of larger magnitude is required, the work function of the metal should be smaller, such as around 4.8 eV, which will result in a threshold voltage of around −0.2 volts. Mid-gap work functions around 4.6 eV will result in threshold voltages with equal magnitudes of around 0.5 eV, but these magnitudes are too large for modern nanometer-scale devices with low power supply voltages that require threshold voltages of about 0.2 to 0.3 volts.

Therefore, there is a need for improved CMOS transistor design.

### SUMMARY

Gates of at least one of the NMOS transistors and PMOS transistors of a CMOS integrated circuit are formed with a solid-solution alloy of at least two metals. The work function of the gate electrode is tunable by controlling the selection of the metals or the relative proportion of the metals that form a layer of the solid-solution alloy.

In one embodiment, a CMOS device includes NMOS and PMOS transistors. Gates of the NMOS or PMOS transistors each include a solid-solution alloy of at least two metals.

In one embodiment, a CMOS device includes first and second type transistors. The first type MOS transistors each include a gate including a layer of a solid-solution alloy of a first metal and a second metal. The second type MOS transistors each include a gate including a layer of at least one of the first metal and the second metal. In a specific embodiment, the first type MOS transistors are NMOS transistors, and the second type MOS transistors are PMOS transistors. In another specific embodiment, the first type MOS transistors are PMOS transistors, and the second type MOS transistors are NMOS transistors.

In one embodiment, a method for producing a CMOS device is provided. A solid-solution alloy of at least two metals is formed in the process of forming at least one of the gate of an NMOS transistor and the gate of a PMOS transistor.

In one embodiment, a method for producing a CMOS device is provided. A first metal is deposited onto gate areas of both first type transistors and second type transistors. A second metal is deposited onto the gate areas of the second type transistors after the first metal is deposited. A solid-solution alloy of the first metal and the second metal is formed in the gate area of the second type transistors by annealing after the second metal is deposited. In a specific embodiment, the first type MOS transistors are NMOS transistors, and the second type MOS transistors are PMOS transistors. In another specific embodiment, the first type MOS transistors are PMOS transistors, and the second type MOS transistors are NMOS transistors.

This Summary is an overview of some of the teachings of the present application and is not intended to be an exclusive or exhaustive treatment of the present subject matter. Further details about the present subject matter are found in the detailed description and appended claims. Other aspects of the invention will be apparent to persons skilled in the art upon reading and understanding the following detailed description and viewing the drawings that form a part thereof. The scope of the present invention is defined by the appended claims and their legal equivalents.

### BRIEF DESCRIPTION OF THE DRAWINGS

The drawings illustrate generally, by way of example, but not by way of limitation, various embodiments discussed in the present document.

FIGS. 1A-1C are illustrations of desired energy bands and work functions for CMOS transistors.

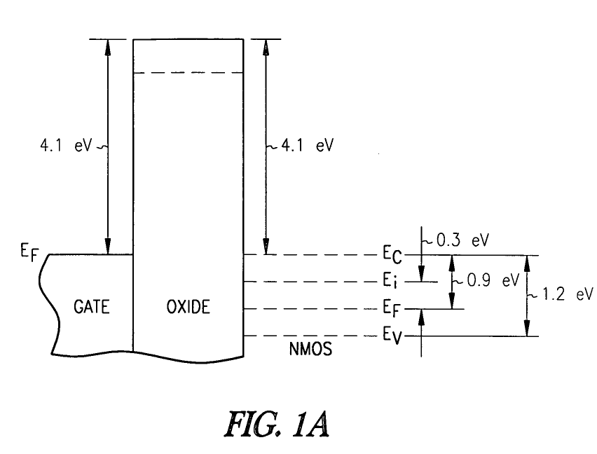

FIG. 2 is an illustration of an embodiment of a structure of portions of a CMOS device showing an NMOS transistor and a PMOS transistor.

FIGS. 3A-3C are each an illustration of an embodiment of gates of the NMOS transistor and the PMOS transistor after metal deposition and before annealing.

FIGS. 4A-4C are each an illustration of an embodiment of gates of the NMOS transistor and the PMOS transistor after the annealing.

FIG. 5 is a block diagram illustrating an embodiment of a memory device utilizing the CMOS device of FIG. 2.

FIG. 6 is a block diagram illustrating an embodiment of a processor-based system utilizing the CMOS device of FIG. 2.

### DETAILED DESCRIPTION

In the following detailed description, reference is made to the accompanying drawings which form a part hereof, and in which is shown by way of illustration specific embodiments in which the invention may be practiced. These embodiments are described in sufficient detail to enable those skilled in the art to practice the invention, and it is to be understood that the embodiments may be combined, or that other embodiments may be utilized and that structural, logical and electrical changes may be made without departing from the spirit and scope of the present invention. References to “an”, “one”, or “various” embodiments in this disclosure are not necessarily to the same embodiment, and such references contemplate more than one embodiment. The following detailed description provides examples, and the scope of the present invention is defined by the appended claims and their legal equivalents.

In this document, a “MOS transistor” refers to a metal-oxide semiconductor field-effect transistor (or MOSFET), an “NMOS transistor” refers to an n-channel metal-oxide semiconductor field-effect transistor (or n-channel MOSFET), and a “PMOS” refers to a p-channel metal-oxide semiconductor field-effect transistor (or p-channel MOSFET). An “NMOS gate” refers to the gate of an NMOS transistor. A “PMOS gate” refers to the gate of a PMOS transistor.

This document discusses, among other things, CMOS transistors having gates formed with solid-solution alloys of metals. The choice of the metals and the relative weight of the metals determine the work function of the gate electrode. The solid-solution alloy is formed by deposition of metal layers and subsequently annealing. In various embodiments, at least one metal layer is formed by atomic layer deposition (ALD). In one embodiment, a CMOS device includes one type of transistors each having a gate formed with a single metal and another type of transistors each having a gate formed with a solid-solution alloy. In another embodiment, a CMOS device includes one type of transistors each having a gate formed with a first type solid-solution alloy and another type of transistors each having a gate formed with a second type solid-solution alloy. The first type solid-solution alloy and the second type solid-solution alloy have substantially different compositions (with different metals or different proportion of metals). In various specific embodiments, the metals and solid-solution alloys used to form the gates of one or more types of transistors in a CMOS device include, but are not limited to, molybdenum (Mo), titanium (Ti), ruthenium (Ru), tantalum (Ta), vanadium (V) molybdenum-titanium (Mo—Ti) alloy, vanadium-molybdenum (V—Mo) alloy, and ruthenium-tantalum (Ru—Ta) alloy.

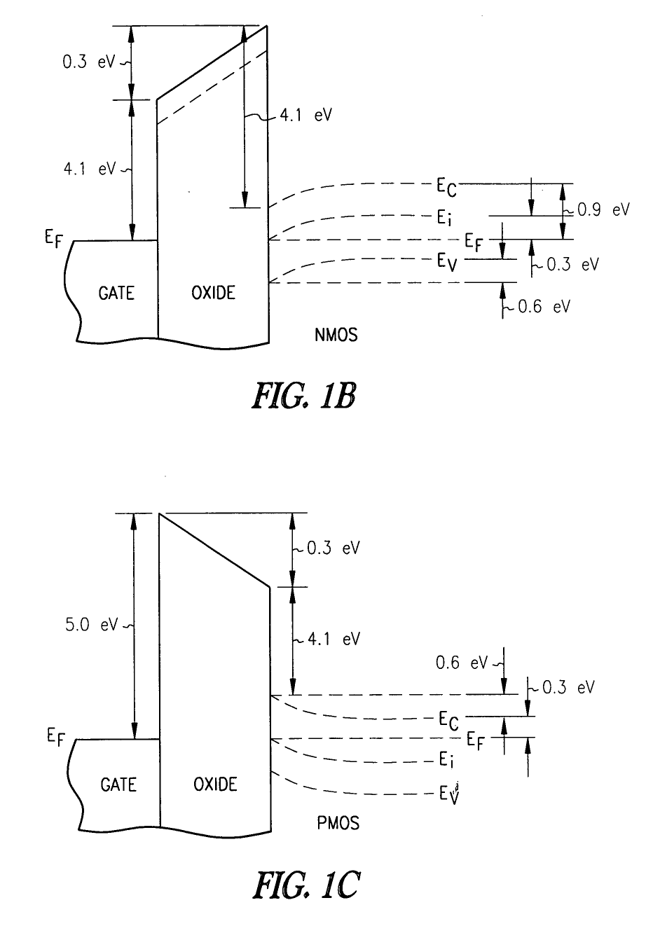

FIG. 2 is an illustration of an embodiment of a structure of portions of a CMOS device 200 including at least an NMOS transistor 201 and a PMOS transistor 221. NMOS transistor 201 and PMOS transistor 221 each have a gate formed by a metal or a solid-solution alloy of at least two metals.

NMOS transistor 201 has a structure including a source region 202, a drain region 204, and a channel 206 between source region 202 and drain region 204. A gate 210 is separated from channel 206 by a gate insulator 208. PMOS transistor 221 has a structure including a source region 222, a drain region 224, and a channel 226 between source region 222 and drain region 224. A gate 230 is separated from channel 226 by a gate insulator 228. In some embodiments, as illustrated in FIG. 2, a conducting layer 212 is deposited on gate 210, and a conducting layer 232 is deposited on gate 230. Conducting layers 212 and 232 are each made of highly conductive materials such as a highly conductive polysilicon or a metal.

In various embodiments, at least one of gate 210 and gate 230 is formed by a solid-solution alloy of at least two metals. The metals are deposited layer by layer, and the solid-solution alloy is formed by high-temperature annealing subsequent to the deposition of the metals. In various embodiments, at least one layer of metal is deposited using ALD. Specific examples of device 200 and the formation of the gate 210 and 230 are discussed below.

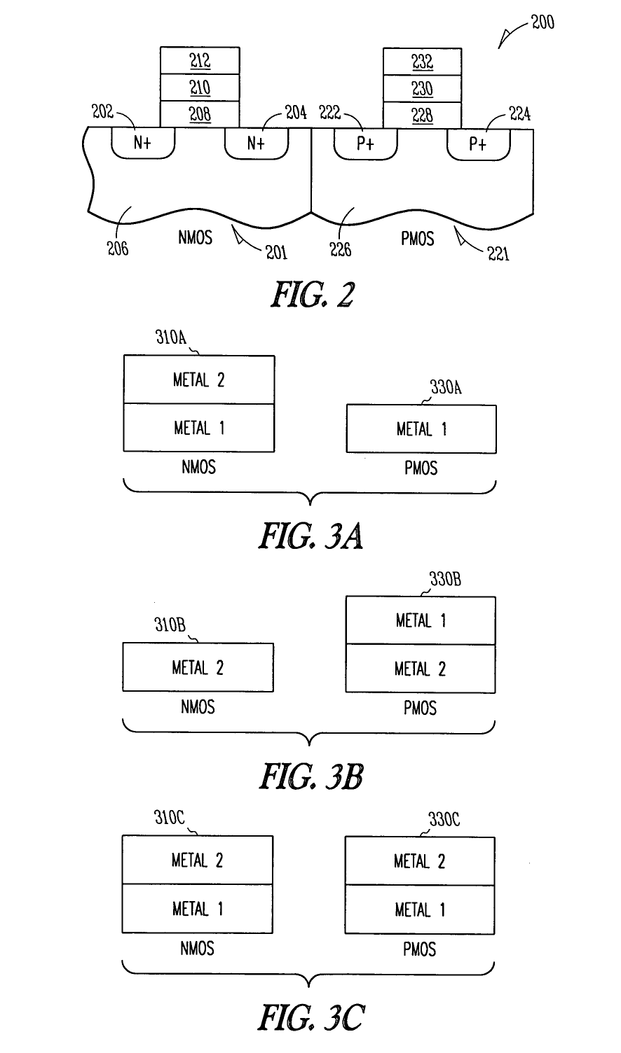

FIGS. 3A-3C are each an illustration of an embodiment of gates of NMOS and PMOS transistors after the metal deposition and before the annealing. The gates are formed with at least two metals, labeled as Metal 1 and Metal 2. In various embodiments, at least one of Metal 1 and Metal 2 is deposited by ALD. In one embodiment, Metal 1 is molybdenum, and Metal 2 is titanium. In another embodiment, Metal 1 is molybdenum, and Metal 2 is vanadium. In another embodiment, Metal 1 is tantalum, and Metal 2 is ruthenium. In addition to the choice of the metals, the work function of each gate is tunable by controlling the relative thickness of the layers of Metal 1 and Metal 2 during the deposition.

FIG. 3A illustrates an NMOS gate 310A and a PMOS gate 330A. NMOS gate 310A illustrates a specific embodiment of gate 210 of NMOS transistor 201. PMOS gate 330A illustrates a specific embodiment of gate 230 of PMOS transistor 221. To form NMOS gate 310A, Metal 1 is deposited first, and Metal 2 is deposited on Metal 1. To form PMOS gate 330A, only Metal 1 is deposited.

FIG. 3B illustrates an NMOS gate 310B and a PMOS gate 330B. NMOS gate 310B illustrates another specific embodiment of gate 210 of NMOS transistor 201. PMOS gate 330B illustrates another specific embodiment of gate 230 of PMOS transistor 221. To form NMOS gate 310B, only Metal 2 is deposited. To form PMOS gate 330B, Metal 2 is deposited first, and Metal 1 is deposited on Metal 2.

FIG. 3C illustrates an NMOS gate 310C and a PMOS gate 330C. NMOS gate 310C illustrates another specific embodiment of gate 210 of NMOS transistor 201. PMOS gate 330C illustrates another specific embodiment of gate 230 of PMOS transistor 221. To form NMOS gate 310C, Metal 1 is deposited first, and Metal 2 is deposited on Metal 1. To form PMOS gate 330C, Metal 1 is deposited first, and Metal 2 is deposited on Metal 1. The work function of each of gate 310C and 330C is tunable by controlling the relative thickness of the layers of Metal 1 and Metal 2.

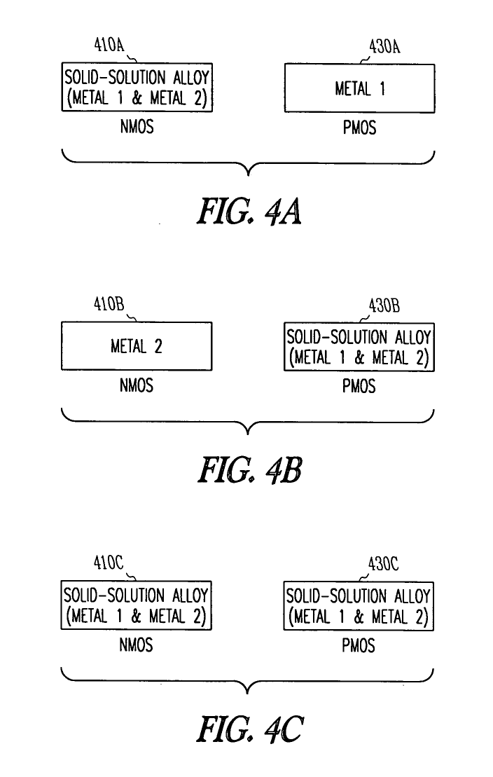

FIGS. 4A-4C are each an illustration of an embodiment of gates of the NMOS transistor and the PMOS transistor after the annealing. After the metal layers as illustrated in FIGS. 3A-3C are deposited, a high temperature anneal is performed, resulting in metal gates illustrated in FIGS. 4A-4C. In one embodiment, in which Metal 1 is molybdenum and Metal 2 is titanium, the annealing temperature is in a range of 450° C. to 875° C. In another embodiment, in which Metal 1 is tantalum and Metal 2 is ruthenium, the annealing temperature is in a range of 500° C. to 1200° C. In one embodiment, the annealing is performed in a vacuum. In another embodiment, the annealing is performed in an inert gas such as helium (He) or argon (Ar).

FIG. 4A illustrates an NMOS gate 410A and a PMOS gate 430A. NMOS gate 410A illustrates a specific embodiment of gate 210 of NMOS transistor 201. PMOS gate 430A illustrates a specific embodiment gate 230 of PMOS transistor 221. NMOS gate 410A includes a layer of the solid-solution alloy of Metal 1 and Metal 2. PMOS gate 430A includes a layer of Metal 1.

FIG. 4B illustrates an NMOS gate 410B and a PMOS gate 430B. NMOS gate 410B illustrates another specific embodiment of gate 210 of NMOS transistor 201. PMOS gate 430B illustrates another specific embodiment of gate 230 of PMOS transistor 221. NMOS gate 410B includes a layer of Metal 2. PMOS gate 430B includes a layer of the solid-solution alloy of Metal 1 and Metal 2.

FIG. 4C illustrates an NMOS gate 410C and a PMOS gate 430C. NMOS gate 410C illustrates another specific embodiment of gate 210 of NMOS transistor 201. PMOS gate 430C illustrates another specific embodiment of gate 230 of PMOS transistor 221. NMOS gate 410C includes a layer of the solid-solution alloy of Metal 1 and Metal 2. PMOS gate 430C includes a layer of the solid-solution alloy of Metal 1 and Metal 2. In one embodiment, the solid-solution alloys of NMOS gate 410C and PMOS gate 430C have substantially different proportions of Metal 1 and Metal 2, resulting from different thicknesses of Metal 1 and Metal 2 deposited before annealing.

The CMOS transistor gates and the processes are discussed with reference to FIGS. 3A-3C and 4A-4C as examples for illustrative purpose only. For example, Metal 1 and Metal 2 may be deposited in a different order. In general, deposition of one or more metals and the subsequent annealing, which results in solid-solution alloys when more than one metal is deposited to form a gate, allows adjustment of the work function to optimize the threshold voltage of CMOS transistors. Specific embodiments are discussed below for several metals. In various embodiments, during fabrication of a CMOS device, at least one of the gate metals is deposited using ALD.

Molybdenum has a high work function of 4.9 eV and has been used for gates in CMOS transistors. Molybdenum can be alloyed with titanium. Molybdenum is completely soluble in titanium at high temperatures, and there is a significant solubility of titanium in molybdenum at room temperature. In one embodiment, molybdenum is deposited by ALD on both NMOS and PMOS gate areas. To provide a higher work function gate for the PMOS transistors, titanium is deposited on the NMOS gate area but not the PMOS gate area. Molybdenum and beta titanium are isomorphic with 80% titanium being completely soluble with molybdenum above the alpha-beta transition temperature at 882° C. It is estimated that the room temperature solubility is at or near 50%. By adjusting the thickness of the titanium layer, the work function of the NMOS metal gate alloy can be changed, for example, from that of titanium (4.3 eV) by using a larger proportion of titanium to that of molybdenum (4.9 eV) by using a smaller proportion of titanium. An NMOS transistor gate metal of larger work function increases the NMOS threshold voltage (to a positive value with higher magnitude), requiring a larger gate voltage to turn the transistor on and enhance conduction. The NMOS gate metal work function can thus be tuned over a range of values to give a desired NMOS threshold voltage.

In another embodiment, titanium is deposited on both NMOS and PMOS gate areas, while only molybdenum is deposited on the PMOS gate area. There is a large solid solubility of titanium in molybdenum. By annealing in the beta phase region, a solid-solution molybdenum-titanium alloy is formed with a work function that is less than that of molybdenum alone (4.9 eV). In order to insure proper operation, it is desirable that the metal in contact with the silicon be a single phase material either thermodynamically stable or meta-stable over the life of the product. Although most alloy compositions of titanium and molybdenum may not be thermodynamically stable at room temperature, all but the very titanium rich compositions are meta-stable in the beta phase at room temperature. This allows lowering of the PMOS threshold voltage (to a negative value of larger magnitude), requiring a larger magnitude gate voltage to turn the PMOS transistor on and enhance conduction.

In another embodiment, molybdenum is deposited on both NMOS and PMOS transistor gate areas by ALD, and titanium is deposited on both the NMOS and PMOS transistor gate areas to form titanium layers of different thicknesses. By annealing, a solid-solution molybdenum-titanium alloy is formed on gate areas of both the NMOS and PMOS transistor. The tunable work function, and hence threshold voltage, is tunable by controlling the thickness of the titanium layer for both the NMOS and PMOS transistors.

In one study (Juppo et al., J. Vac, Sci. Technol., A 16(5):2845-50 (1998)), molybdenum thin films were deposited onto both soda lime glass and Al₂O₃ film by an alternate supply of MoCl₅ and Zinc (Zn). Zinc was used as a reducing agent. The film growth was performed over a temperature range of 560° C. to 600° C. in order to study the temperature effect on the growth. In addition to the growth temperature, the purge length after zinc was also seen to have a considerable effect of the growth.

Ruthenium has a high work function of 5.1 eV and can be alloyed in a solid solution with tantalum, which has a work function of 4.2 eV. Ruthenium can be alloyed into tantalum to form a solid-solution alloy with up to 40% ruthenium, while tantalum is soluble up to 20% in ruthenium. Ruthenium can be deposited by ALD. In one embodiment, ruthenium is deposited on both NMOS and PMOS gate areas. Tantalum is deposited on the NMOS gate area but not the PMOS gate area. By adjusting the thickness of the ruthenium layer, a desirable work function, 4.7 eV for example, results after annealing from an appropriate ruthenium-tantalum volume ratio. An NMOS transistor gate metal of larger work function increases the NMOS threshold voltage (to a positive value of larger magnitude), for example, when it is desirable to require a larger gate voltage to turn the NMOS transistor on and enhance conduction.

In another embodiment, ruthenium is deposited on both NMOS and PMOS gate areas. Tantalum is deposited on the PMOS gate area but not the NMOS gate area. As noted, there is a 20% solubility of tantalum in ruthenium. By annealing, a solid-solution alloy is formed with a work function less than that of ruthenium alone, thus allowing lowering of the PMOS threshold voltage (to a negative value of larger magnitude), for example, when it is desirable to have a larger magnitude negative gate voltage to turn the PMOS transistor on and enhance conduction. Although the required materials may be deposited by several different methods, the use of ALD has a potentially significant advantage in that thin precisely controlled layers of the desired materials may be deposited. This is advantageous in two respects. The first is that the compositions may be controlled to a high degree of accuracy. The second is that the alloy may be made up of thin layers of each metal. This allows for a shorter annealing time and/or a lower annealing temperature.

An example of the use of ruthenium metal gate on La-oxidegate insulators is discussed in U.S. patent application Ser. No. 10/926,812, entitled “RUTHENIUM GATE FOR A LANTHANIDE OXIDE DIELECTRIC LAYER,” filed on Aug. 26, 2004, assigned to Micron Technology, Inc, which is hereby incorporated by reference in their entirety. Use of Ru(thd)₃, tris(2,2,6,6-tetramethyl-3,5-heptanedionato) ruthenium, and oxygen for ALD of ruthenium thin films at temperatures between 325° C. and 450° C. was studied (Aaltonen et al., Chem. Vap. Deposition, 10(4):215-19 (2004)). Polycrystalline ruthenium films with a preferred orientation were deposited. The films had resistivities <20 μΩcm and they adhered well to a thin Al₂O₃ film on glass. Metallic ruthenium grown by ALD in the temperature range of 275-560° C. using bis(cyclopentadienyl)ruthenium (RuCp₂) and oxygen as precursors was studied (Aaltonen et al., Chem. Vap. Deposition, 9(1):45-49 (2003)). The films had resistivities below 20 μΩcm (11.6 μΩcm at 560° C.). ALD of ruthenium using Ru(od)₃/n-butyl-acetate solution (0.1 M) (here od is octane-2,4-dionate) and oxygen gas was studied (Min et al., Adv. Mater., 15(12):1019-22 (2003)). The process window of ALD appeared in the temperature region from 325-375° C. ALD of metals and diffusion barriers was studied using a new Ru(II) precursor, Ru(amd)₂ (CO)₂, bis(N,N′)diisopropylacetamidinato)-ruthenium(II) dicarbonyl with reducing agent of H₂ (Gordon, American Vac. Soc. Conference, San Jose, Calif., (Aug. 4, 2003)). The results include a graph showing deposition rate versus temperature ranging from 200° C. to 280° C. Plasma-enhanced ALD of ruthenium thin films was studied (Kwon et al., Electrochem. and Solid-State Lett., 7(4):C46-48 (2004)). The metallic precursor was bis(ethylcyclopentadinyl)ruthenium [Ru(Et(Cp)₂] and NH₃ plasma. NH₃ plasma acted as an effective reducing agent for Ru(Et(Cp)₂. Typical resistivity was 12 μΩcm. Ruthenium, palladium and platinum complexes of 2,2,6,6-tetramethyl-3,5-heptanedione (thd) and ruthenium tris acetylacetonate (asas) were synthesized and studied with TG, DTA, DSC and MS methods (Lashdaf et al., J. Thermal Analysis and Calorimetry, 64(3):1171-82 (2001)). The platinum thd complex has the highest volatility despite the second highest molecular mass of the complex. All the complexes sublimed under reduced pressure.

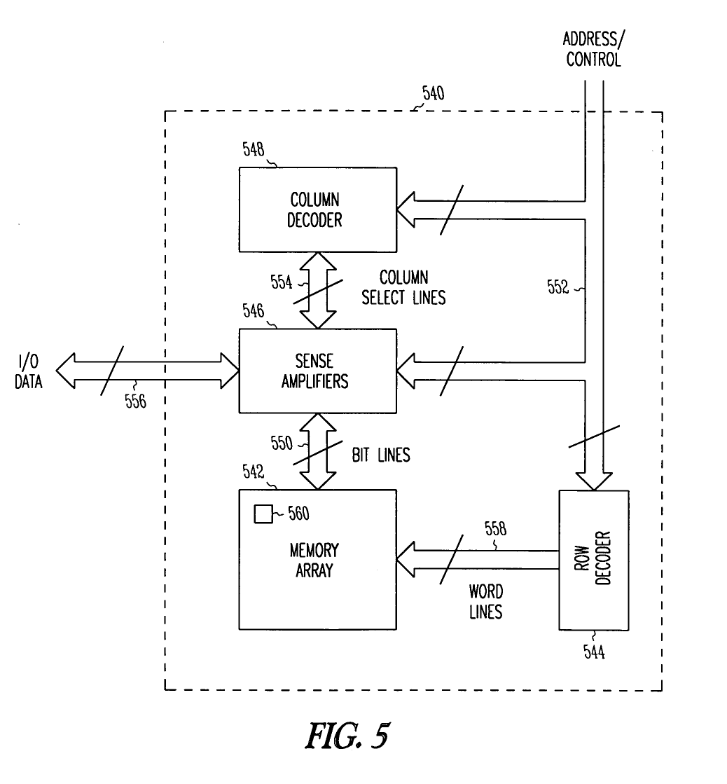

FIG. 5 is a block diagram illustrating an embodiment of a memory device 540 utilizing the CMOS device of FIG. 2. Memory device 540 contains a memory array 542, a row decoder 544, a column decoder 548, and sense amplifiers 546. Memory array 542 includes a plurality of transistor cells 560 that have gates formed with a metal or a solid-solution alloy of metals as discussed above. Word lines 558 and bit lines 550 are commonly arranged into rows and columns. Bit lines 550 of memory array 542 are connected to sense amplifiers 546, while word lines 558 are connected to row decoder 544. Address and control signals are input on address/control lines 552 into memory device 540 and are connected to column decoder 548, sense amplifiers 546 and row decoder 544 and are used to gain read and write access, among other things, to memory array 542.

Column decoder 548 is connected to sense amplifiers 546 via control and column select signals on column select lines 554. Sense amplifiers 546 receives input data destined for memory array 542, and outputs data read from memory array 542 over input/output (I/O) data lines 556. Data is read from the cells of memory array 542 by activating one of the word lines 558 (via the row decoder 544), which couples all of the memory cells corresponding to that word line to respective bit lines 550, which define the columns of the array. One or more bit lines 550 are also activated. When a particular word line 558 and bit lines 550 are activated, sense amplifiers 546 connected to a bit line column detects and amplifies the conduction sensed through a given transistor cell and transferred to its bit line 550 by measuring the potential difference between the activated bit line 550 and a reference line which may be an inactive bit line. In the read operation the source region of a given cell is coupled to bit line. The operation of Memory device sense amplifiers is described, for example, in U.S. Pat. Nos. 5,627,785; 5,280,205; and 5,042,011, all assigned to Micron Technology Inc., which are incorporated by reference herein in their entirety.

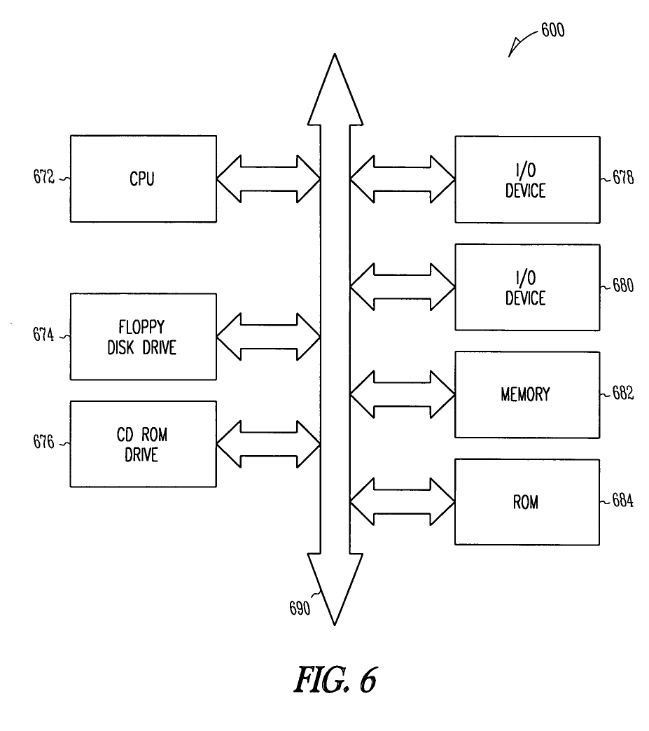

FIG. 6 is a block diagram illustrating an embodiment of a processor-based system utilizing the CMOS device of FIG. 2. FIG. 6 is a block diagram of an electrical system, or processor-based system, 600 utilizing transistor cells having gates formed with a metal or a solid-solution alloy of metals as discussed above. For example, by way of example and not by way of limitation, memory 682 is constructed in accordance with the present invention to have transistor cells having ternary metallic gates formed by atomic layer deposition. However, the present subject matter is not so limited and the same can apply to transistors in the CPU, etc. The processor-based system 600 may be a computer system, a process control system or any other system employing a processor and associated memory. System 600 includes a central processing unit (CPU) 672, e.g., a microprocessor that communicates with the memory 682 and an I/O device 678 over a bus 690. It is noted that bus 690 may be a series of buses and bridges commonly used in a processor-based system, but for convenience purposes only, bus 690 has been illustrated as a single bus. A second I/O device 680 is illustrated, but is not necessary to practice the invention. The processor-based system 600 can also include read-only memory (ROM) 684 and may include peripheral devices such as a floppy disk drive 674 and a compact disk (CD) ROM drive 676 that also communicates with the CPU 672 over the bus 690 as is well known in the art.

It will be appreciated by those skilled in the art that additional circuitry and control signals can be provided, and that the processor-based system 600 has been simplified to help focus on the invention.

It is to be understood that FIG. 6 illustrates an embodiment for electronic system circuitry in which one or more CMOS devices, each including transistor gates formed with one or more solid-solution alloys, are used. The illustration of system 600, as shown in FIG. 6, is intended to provide a general understanding of one application for the structure and circuitry of the present invention, and is not intended to serve as a complete description of all the elements and features of an electronic system using the novel ternary metallic gate transistor cells formed by atomic layer deposition. Further, the invention is equally applicable to any size and type of system 600 using the one or more CMOS devices each including transistor gates formed with one or more solid-solution alloys, and is not intended to be limited to that described above. As one of ordinary skill in the art will understand, such an electronic system can be fabricated in single-package processing units, or even on a single semiconductor chip, in order to reduce the communication time between the processor and the memory device.

Applications containing the one or more CMOS devices each including transistor gates formed with one or more solid-solution alloys, as described in this disclosure, include electronic systems for use in memory modules, device drivers, power modules, communication modems, processor modules, and application-specific modules, and may include multilayer, multichip modules. Such circuitry can further be a subcomponent of a variety of electronic systems, such as a clock, a television, a cell phone, a personal computer, an automobile, an industrial control system, an aircraft, and others.

This disclosure includes several processes and structures. The present invention is not limited to a particular process order or structural arrangement. Although specific embodiments have been illustrated and described herein, it will be appreciated by those of ordinary skill in the art that any arrangement which is calculated to achieve the same purpose may be substituted for the specific embodiments shown. This application is intended to cover adaptations or variations. It is to be understood that the above description is intended to be illustrative, and not restrictive. Combinations of the above embodiments, and other embodiments, will be apparent to those of skill in the art upon reviewing the above description. The scope of the present invention should be determined with reference to the appended claims, along with the full scope of equivalents to which such claims are entitled.

What is claimed is:

1. A CMOS device, comprising:
first type MOS transistors each including a first type gate including a layer of a solid-solution alloy of a first metal and a second metal; and
second type MOS transistors each including a second type gate including a layer of at least one of the first metal and the second metal.

2. The CMOS device of claim 1, wherein the first type MOS transistors comprise NMOS transistors, and the second type MOS transistors comprise PMOS transistors.

3. The CMOS device of claim 1, wherein the first type MOS transistors comprise PMOS transistors, and the second type MOS transistors comprise NMOS transistors.

4. The CMOS device of claim 1, wherein the solid-solution alloy is formed by forming a layer of the first metal, forming a layer of the second metal, and annealing.

5. The CMOS device of claim 4, wherein at least one of the layer of the first metal and the layer of the second metal is formed by atomic layer deposition.

6. The CMOS device of claim 5, wherein the first metal is titanium (Ti), and the second metal is molybdenum (Mo).

7. The CMOS device of claim 5, wherein the first metal is vanadium (V), and the second metal is molybdenum (Mo).

8. The CMOS device of claim 5, wherein the first metal is tantalum (Ta), and the second metal is ruthenium (Ru).

9. A CMOS device, comprising:
an NMOS transistor including an NMOS gate; and
a PMOS transistor including a PMOS gate,
wherein at least one of the NMOS gate and the PMOS gate includes a solid-solution alloy of a first metal and a second metal formed by depositing the first metal, depositing the second metal, and annealing.

10. The CMOS device of claim 9, wherein the first metal is titanium (Ti), and the second metal is molybdenum (Mo).

11. The CMOS device of claim 10, wherein the NMOS gate includes the solid-solution alloy, and the PMOS gate includes titanium (Ti).

12. The CMOS device of claim 10, wherein the PMOS gate includes the solid-solution alloy, and the NMOS gate includes molybdenum (Mo).

13. The CMOS device of claim 9, wherein the first metal is tantalum (Ta), and the second metal is ruthenium (Ru).

14. The CMOS device of claim 13, wherein the NMOS gate includes the solid-solution alloy, and the PMOS gate includes ruthenium (Ru).

15. The CMOS device of claim 13, wherein the PMOS gate includes the solid-solution alloy, and the NMOS gate includes tantalum (Ta).

16. A method for producing a CMOS device, the method comprising:
depositing a first metal onto gate areas of first type transistors and gate areas of second type transistors;
depositing a second metal onto the gate areas of the second type transistors after the first metal is deposited; and
forming a solid-solution alloy of the first metal and the second metal in the gate area of the second type transistors by annealing after the second metal is deposited.

17. The method of claim 16, wherein at least one of depositing the first metal and depositing the second metal comprises performing atomic layer deposition.

18. The method of claim 17, wherein annealing comprises annealing in a vacuum.

19. The method of claim 17, wherein annealing comprises annealing in an inert gas.

20. The method of claim 19, wherein annealing comprises annealing in one or more of helium (He) and argon (Ar).

21. The method of claim 17, wherein annealing comprises annealing at a temperature between 450 and 700 degrees Celsius.

22. The method of claim 21, wherein depositing the first metal comprises depositing molybdenum (Mo), and depositing the second metal comprises depositing titanium (Ti).

23. The method of claim 21, wherein depositing the first metal comprises depositing titanium (Ti), and depositing the second metal comprises depositing molybdenum (Mo).

24. The method of claim 17, wherein annealing comprises annealing at a temperature between 600 and 1200 degrees Celsius.

25. The method of claim 24, wherein depositing the first metal comprises depositing tantalum (Ta), and depositing the second metal comprises depositing ruthenium (Ru).

26. The method of claim 24, wherein depositing the first metal comprises depositing ruthenium (Ru), and depositing the second metal comprises depositing tantalum (Ta).

27. A method for producing a CMOS device, the method comprising:
forming an NMOS gate for an NMOS transistor; and
forming a PMOS gate for a PMOS transistor,
wherein at least one of the forming the NMOS gate and the forming the PMOS gate includes:
forming a first metal layer by depositing the first metal;
forming a second metal layer on the first metal layer by depositing the second metal; and
forming a layer of a solid-solution alloy by annealing.

28. The method of claim 27, further comprising controlling a threshold voltage of at least one of the NMOS transistor and the PMOS transistor by controlling the relative thicknesses of the first and second metal layers.

29. The method of claim 27, wherein forming the first metal layer comprises forming the first metal layer by atomic layer deposition of the first metal.

30. The method of claim 27, wherein forming the second metal layer comprises forming the second metal layer by atomic layer deposition of the second metal.

31. The method of claim 27, wherein the first metal is molybdenum (Mo).

32. The method of claim 31, wherein the second metal is titanium (Ti).

33. The method of claim 27, wherein the first metal is titanium (Ti).

34. The method of claim 33, wherein the second metal is molybdenum (Mo).

35. The method of claim 27, wherein the first metal is ruthenium (Ru).

36. The method of claim 35, wherein the second metal is tantalum (Ta).

37. The method of claim 27, wherein the first metal is tantalum (Ta).

38. The method of claim 37, wherein the second metal is ruthenium (Ru).
